(19) United States
(12) Patent Application Publication
(10) Pub. No.: US 2009/0027136 A1
(43) Pub. Date: Jan. 29, 2009

(54) ACTIVE ELECTROMAGNETIC INTERFERENCE FILTER CIRCUIT FOR SUPPRESSING A LINE CONDUCTED INTERFERENCE SIGNAL

(75) Inventors: Boris Willebroidus Traa, Eindhoven (NL); Age Jochem Van Dalfsen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/573,918

(22) PCT Filed: Aug. 18, 2005
(86) PCT No.: PCT/IB05/52716

§ 371 Date: Feb. 19, 2007

(30) Foreign Application Priority Data
Aug. 31, 2004 (EP) 04104173.2

(51) Int. Cl. H03H 11/10; H03H 1/00

(52) U.S. Cl. 333/12; 333/214

(57) ABSTRACT

The invention relates to an Electromagnetic Interference (EMI) filter circuit (Fa) for suppressing a Line Conducted Interference (LCI) signal. The EMI filter circuit (Fa) comprises a filter inductance (Lo) to carry a supply current (Isup) between a supply voltage (Vsup) and a load (L). The EMI filter circuit (Fa) further comprises an active circuit (Ca), arranged in parallel with the filter inductance (Lo). The active circuit (Ca) comprises a sensing circuit (Mm) to sense the LCI signal and further comprises a suppressing circuit (Ms) to suppress the LCI signal. In an embodiment of the active EMI filter circuit (Fa), the active circuit (Ca) comprises a negative inductance generating circuit to create a negative inductance value. Selecting the negative inductance generating circuit to create an inductance value (Lca) larger than the inductance value of the filter inductance (Lo) creates a resulting inductance (Lr) which is higher compared to the inductance value of the filter inductance (Lo). In one embodiment, the negative inductance generating circuit comprises a negative impedance converter.

### FIELD OF THE INVENTION

The invention relates to an active Electromagnetic Interference filter for suppressing a Line Conducted Interference signal.

The invention further relates to a Common Mode suppression filter, to a power converter comprising the active Electromagnetic Interference filter and to an apparatus.

### BACKGROUND OF THE INVENTION

High frequency common-mode signals generated by a system affect other electronic equipment which is connected to a point of common coupling such as the mains. Suppression of the high frequency common-mode signals is usually obtained by a filter coil arranged between the system and the mains. The system together with the filter coil and the mains form a closed loop. In a simplified equivalent RF-diagram of this loop, the mains is represented by its common mode mains impedance. This common mode mains impedance is connected between a reference potential (usually ground) and one terminal of the filter coil. The other terminal of the filter coil is connected to the system which is represented by a series arrangement of an RF noise voltage source and a noise source output impedance. The series arrangement of the RF noise source and the noise source output impedance is connected between the other terminal of the filter coil and the reference potential. Thus a closed loop is present for RF signals such as the high frequency common mode signals. The total impedance in the closed loop determines the level of a high frequency common mode noise current caused by the RF noise voltage source. In practical applications, the total impedance of the closed loop can be enlarged by enlarging the impedance of the filter coil. Alternatively, suppression of line conducted Electromagnetic Interference (EMI) may be obtained by using an active filter known from WO 03/005578. In this patent application an active common mode EMI filter is magnetically coupled to a common mode inductor through an auxiliary winding installed on a magnetic core of the common mode inductor. The active EMI filter detects the flow of high-frequency common mode current through the common mode inductor. The common mode inductor only operates as an inductor when common mode current flows through it and a magnetic flux proportional to the common mode current is induced in its magnetic core. This magnetic flux causes an electromotive force in the auxiliary winding, and this electromotive force drives an input of a trans-conductance amplifier of the active common mode EMI filter. The output of the amplifier, which is the output of the active EMI filter, provides a compensation current to ground according to the detected common mode current through an output capacitor. This compensation current counteracts the high-frequency common mode current.

The active filter as disclosed in the prior art document detects the EMI by sensing a current through an inductance and compensates the EMI by circulating a leakage current through one or more coupling capacitors to ground. This requires several filter input terminals and several filter output terminals, making the implementation of the active filter, as disclosed in the prior art document, complex and expensive.

### SUMMARY OF THE INVENTION

It is an object of the invention to provide an easily implementable active EMI filter circuit.

A first aspect of the invention provides an active Electromagnetic Interference filter circuit as claimed in claim 1. A second aspect of the invention provides a Common Mode suppression filter as claimed in claim 8. A third aspect of the invention provides a power converter as claimed in claim 9. A fourth aspect of the invention provides an apparatus as claimed in claim 10. Advantageous embodiments are defined in the dependent claims.

The active Electromagnetic Interference filter circuit in accordance with the first aspect of the invention comprises a filter input terminal and a filter output terminal. A filter inductance is arranged between the filter input terminal and the filter output terminal to carry a supply current between a supply voltage and a load. An active circuit is arranged in parallel with the filter inductance through a circuit input terminal and a circuit output terminal.

The active circuit comprises a sensing circuit to sense the Line Conducted Interference signal between the circuit input terminal and the circuit output terminal to obtain a sense signal. The active circuit further comprises a suppressing circuit which supplies, in response to the sense signal, a counteracting voltage across the circuit input terminal and the circuit output terminal or supplies a counteracting current from the circuit input terminal to the circuit output terminal to counteract the Line Conducted Interference signal. The active Electromagnetic Interference (further also referred to as EMI) filter circuit in accordance with the first aspect of the invention uses the circuit input terminal and the circuit output terminal of the active circuit both to sense the Line Conducted Interference (further also referred to as LCI) signal and to suppress the LCI signal. The filter inductance of the active EMI filter circuit carries the supply current flowing between the supply voltage, which usually is the mains voltage, and the load. The Line Conducted interference signal, which is a high frequency signal superimposed on the supply current, is sensed by the active EMI filter circuit across the filter inductance through the circuit input terminal and the circuit output terminal. In response to the sensed LCI signal, the active circuit generates a suppression signal to the circuit input terminal and/or to the circuit output terminal to counteract or compensate the LCI signal. The benefit of the active EMI filter circuit according to the invention is that the active EMI filter circuit can be considered a one-port electronic component. Therefore, the number of input and output terminals is reduced compared to the prior art solution. This enables the active EMI filter circuit to be applied easily into an existing electronic circuit. These advantages result in an easily implementable EMI filter circuit.

In an embodiment of the active EMI filter circuit in accordance with the invention, the EMI filter circuit is a mains filter which is arranged between the mains and a load. The load, in many applications, comprises a power converter and at least one power consuming circuit. The power converter converts the mains voltage into a power converter voltage required by the power consuming circuit connected to the power converter.

In an embodiment of the active EMI filter circuit in accordance with the invention as claimed in claim 2, the sensing circuit comprises a voltage sensor to obtain the sense signal which is a sensed voltage and the suppressing circuit comprises a current source which is controlled by the sensed voltage to supply the counteracting current. The voltage sensed by the voltage sensor across the filter inductance Lo comprises an LCI voltage. The current source generates the counteracting current, which counteracts the LCI current resulting from the LCI voltage. The generated counteracting current depends on the sensed LCI voltage by the voltage sensor.

In an embodiment in accordance with the invention as claimed in claim 3, the filter inductance has a positive inductance value and the active circuit comprises a negative inductance generating circuit to create a negative inductance value. An inductance having a positive inductance value, also indicated as positive inductance, is, for example, a coil or a transformer. As is indicated in the introductory part of this document, the load, which in a simplified equivalent RF-diagram is represented by the series arrangement of an RF noise voltage source and a noise source output impedance and which is connected to ground (in the introductory part, the load is a system), represents together with the filter inductance and the mains impedance which is connected to ground, a closed loop for LCI signals. The impedance value of this closed loop determines the level of the LCI current. By increasing the impedance for the LCI signals, for example, by adding a filter inductance, the level of the LCI current can be limited. Increasing the filter inductance thus reduces the LCI current in a frequency range of interest. The inventors have realized that the parallel arrangement of a negative inductance generating circuit with the positive filter inductance may result in a higher resulting filter inductance value. For stability reasons, the resulting inductance of the parallel arrangement of the negative inductance generating circuit and the positive inductance must be positive. Negative inductance generating circuits are, for example, disclosed in U.S. Pat. No. 4,315,229 and U.S. Pat. No. 4,147,997 and are applied in signal filters for low-level signal lines to improve the filter characteristics. The signal filters disclosed in the prior art do not show the parallel arrangement of a negative inductance generating circuit with a positive inductance as proposed by the inventors. In addition, the prior art does not disclose the application of a negative inductance generating circuit in high-level supply lines for counteracting LCI signals.

The present invention defines an active EMI filter circuit for reducing LCI signals in a supply line, through an arrangement of a filter inductance in parallel with a negative inductance generating circuit. Using a negative inductance generating circuit in a supply line application enables a higher suppression level using smaller components and thus may lead to miniaturization of supply line EMI filters.

In an embodiment in accordance with the invention as claimed in claims 4, 5, and 6, the negative inductance generating circuit comprises a Negative Impedance Converter. A Negative Impedance Converter (further also referred to as NIC) is an active circuit which is able to invert the sign of an impedance within the circuit. In an embodiment of the NIC as claimed in claim 5, the NIC comprises a circuit input terminal and an circuit output terminal, and further comprises an operational amplifier, a first impedance arranged between an inverting input of the operational amplifier and the circuit output terminal, a second impedance arranged between the inverting input of the operational amplifier and an output of the operational amplifier, and a third impedance arranged between the output of the operational amplifier and a non-inverting input of the operational amplifier. The non-inverting input of the operational amplifier is further connected to the circuit input terminal. The three combinations of the first, second and third impedances as defined in claim 6 result in an NIC which represents the negative inductance value. The benefit of using the described NIC as the negative inductance generating circuit is that it is relatively simple to produce because the described NIC requires only a few standard components.

In an embodiment in accordance with the invention as claimed in claim 7, the filter inductance of the active Electromagnetic Interference filter circuit comprises a transformer which comprises a primary inductance and a secondary inductance which are magnetically coupled. The primary inductance is arranged between the filter input terminal and the filter output terminal. The secondary inductance is arranged in parallel with the active circuit through the circuit input terminal and the circuit output terminal. Benefits of using a transformer as the filter inductance are that it enables galvanic separation between the active circuit and the remainder of the network and that it offers additional design flexibility to optimize the efficiency of the active EMI filter circuit.

The Common Mode suppression filter in accordance with the second aspect of the invention comprises a first inductance, to carry a supply current from a supply voltage to a load, and a second inductance, to carry a return current from the load to the supply voltage. The first inductance and the second inductance are magnetically coupled to suppress a Common Mode Line conducted interference signal. The Common mode suppression filter comprises the active Electromagnetic Interference filter circuit, wherein the filter inductance constitutes the first inductance or wherein the filter inductance constitutes the second inductance. In an additional configuration, the active circuit may be arranged in parallel with a secondary inductance which is installed as an auxiliary winding on the magnetic core of the Common Mode suppression filter.

These and other aspects of the invention are apparent from and will be elucidated with reference to the embodiments described hereinafter.

### BRIEF DESCRIPTION OF THE DRAWINGS

In the drawings:

FIG. 1A shows a conceptual circuit diagram of the active EMI filter circuit in accordance with the invention,

FIG. 1B shows an embodiment of the active EMI filter circuit in accordance with the invention in which the filter inductance represents a positive inductance and the active circuit acts as a negative inductance,

FIG. 2A shows a representation of a Negative Impedance Converter, and

FIGS. 2B, 2C and 2D show configurations of an active negative inductance, implemented with a Negative Impedance Converter,

FIG. 3 shows an embodiment of the active EMI filter circuit in accordance with the invention, in which a Negative Impedance Converter is applied,

FIG. 4 shows a Negative Impedance Converter which comprises the sensing circuit and suppressing circuit,

FIG. 5 shows an active EMI filter circuit in accordance with the invention wherein the filter inductance is a transformer,

FIG. 6 shows an active EMI filter circuit in accordance with the invention, arranged as a mains filter,

FIG. 7 shows an active Common Mode EMI filter circuit in accordance with the invention,

FIG. 8 shows an electronic apparatus comprising a Power Converter which comprises the active EMI filter circuit in accordance with the invention, and

FIG. 9 shows the representation of the Negative Impedance Converter together with a possible power supply network for the operational amplifier.

### DETAILED DESCRIPTION OF THE PREFERRED EMBODIMENTS

Items having the same references in different figures represent the same elements having the same function. Every inductance, as used throughout this document may comprise a coil, a transformer or any circuit that represents an inductance value. In following figures, if present, a supply voltage Vsup is arranged at the right hand side of the circuitry and a load L at the left hand side.

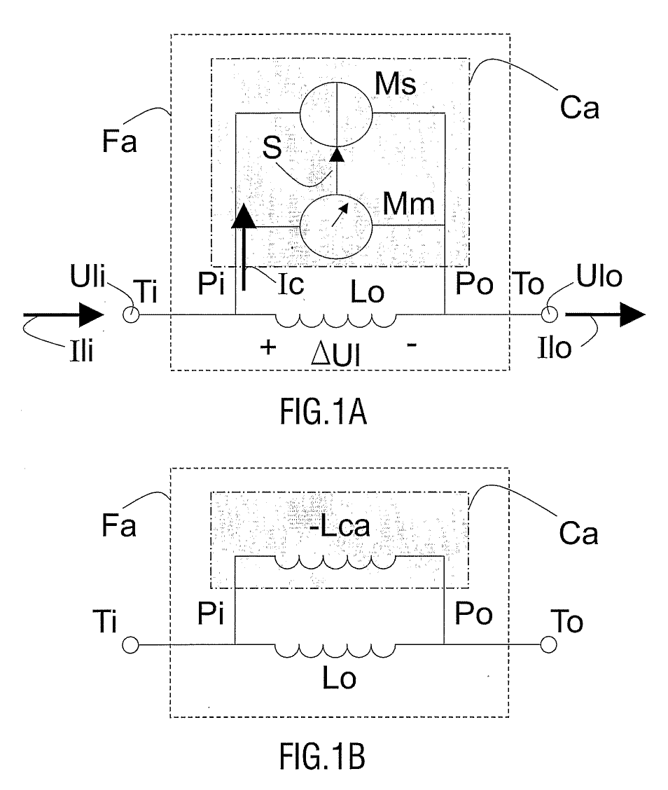

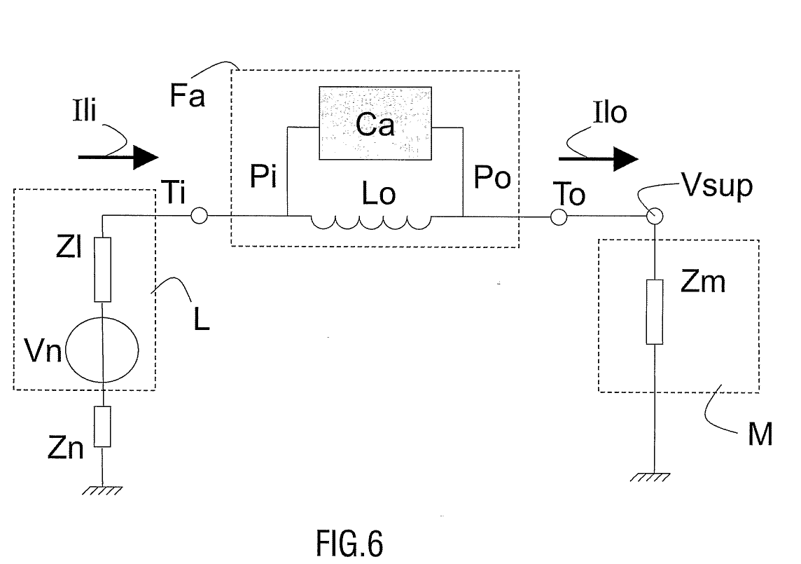

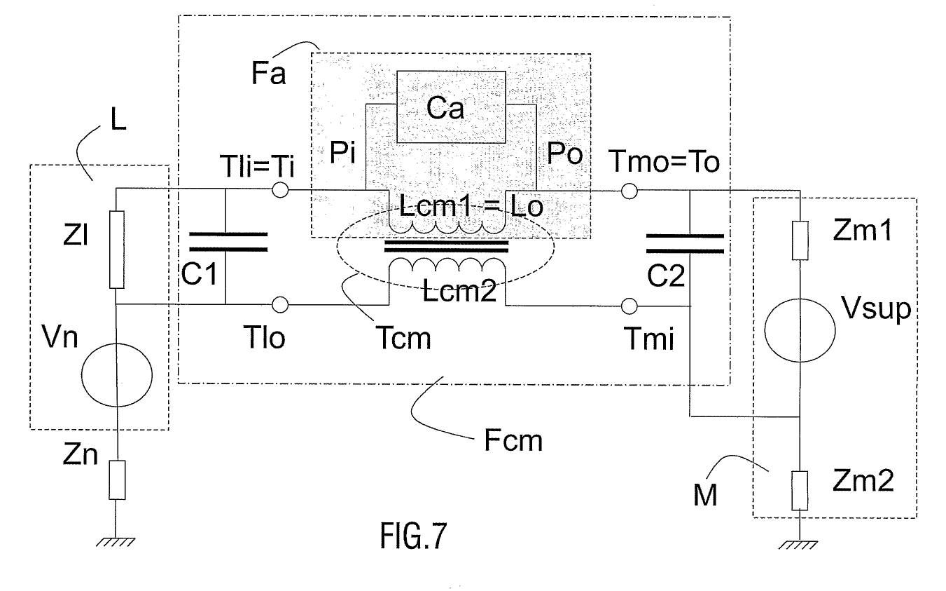

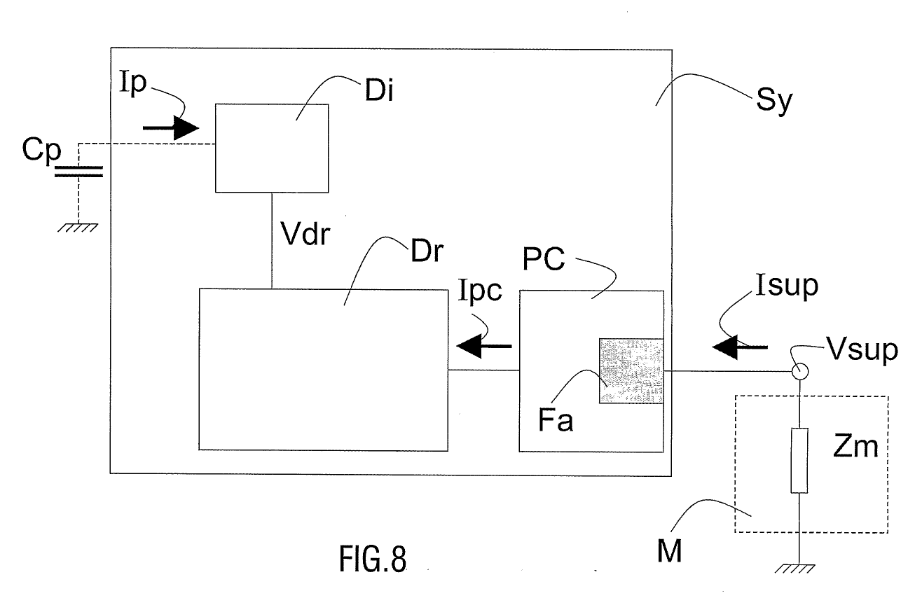

FIG. 1A shows a conceptual circuit diagram of the active EMI filter circuit Fa in accordance with the invention. The active EMI filter circuit Fa, which has a filter input terminal Ti and a filter output terminal To further comprises a filter inductance Lo and an active circuit Ca. The filter inductance Lo is arranged between the filter input terminal Ti and the filter output terminal To. The active circuit Ca comprises a circuit input terminal Pi and a circuit output terminal Po through which it is arranged in parallel with the filter inductance Lo and thus also is arranged between the filter input terminal Ti and the filter output terminal To. The active circuit Ca comprises a sensing circuit Mm which is arranged between the circuit input terminal Pi and the circuit output terminal Po. The active circuit Ca further comprises a suppressing circuit Ms which is arranged between the circuit input terminal Pi and the circuit output terminal Po. The filter inductance Lo carries a supply current Isup (see FIG. 8) flowing between a supply voltage source, usually the mains voltage, and a load L (see FIGS. 6 and 7) as demanded by the load L which usually is an electronic apparatus comprising several circuits. Often a high-frequency LCI signal is superimposed on the supply current Isup which may disturb surrounding electronic circuits via the mains voltage. Such an LCI signal is caused by high frequently signals in at least one of the circuits of the electronic apparatus and which, for example, flow from the circuit to the surroundings via a parasitic capacitance Cp (see FIG. 8). The active EMI filter circuit Fa in accordance with the invention reduces the LCI signal and thus protects surrounding electronic circuits from being disturbed by the LCI signals. The load L is connected to the filter input terminal Ti of the active EMI filter circuit Fa and is considered to supply the high-frequency LCI signal to the filter input terminal Ti. The sensing circuit Mm senses the LCI signal across the filter inductance Lo and generates a sense signal S. The suppressing circuit Ms receives the sense signal S from the sensing circuit Mm and in response suppresses the LCI signal. In one configuration, as shown in FIG. 1A, the sensing circuit Mm is a voltage sensor and the suppressing circuit Ms is a current source. The LCI signal causes a voltage difference ΔUl (ΔUl=Uli−Ulo) across the filter inductance Lo wherein Uli is the potential at the filter input terminal Ti and Ulo is the potential at the filter output terminal To. This voltage difference ΔUl is sensed by the voltage sensor Mm, which generates a sense signal S to the current source Ms. The current source Ms supplies a counteracting current Ic, in response to the received sense signal S, to the circuit input terminal Pi. The supplied counteracting current Ic reduces the LCI current Ili, entering through the input terminal Ti. Because the LCI voltage difference ΔUl is sensed across the circuit input terminal Pi and the circuit output terminal Po and the counteracting current Ic is supplied from the circuit input terminal Pi to the circuit output terminal Po, the circuit input terminal Pi and circuit output terminal Po are used both for sensing and for suppressing the LCI signal. This enables the active EMI filter circuit to be configured as a one-port element.

FIG. 1B shows an embodiment of the active EMI filter circuit Fa in accordance with the invention in which the filter inductance Lo represents a positive inductance and the active circuit Ca acts as a negative inductance −Lca. The filter inductance Lo and the active circuit Ca are arranged in parallel between the filter input terminal Ti and the filter output terminal To of the active EMI filter circuit Fa, identical to the configuration shown in FIG. 1A. In this representation the active circuit Ca is represented by an inductance −Lca having a negative inductance value. Active circuits, which substantially behave like an inductance with a negative inductance value, exist in several configurations. For example, such an active circuit may use one of the following approaches: VAPAR (Variable Active-Passive Reactance), BVI (Bootstrap Variable Inductance), DRS (Direct Reactance Synthesis) and NIC (Negative Impedance Converters). Choosing the absolute inductance value of the negative inductance −Lca to be larger than the inductance value of the filter inductance Lo creates a resulting inductance Lr of which the inductance value is larger than the filter inductance value Lo, according to the following relationship:

$$Lr = \frac{Lo ( - Lca )}{Lo + ( - Lca )}$$

For example, if the filter inductance Lo is 10 milli-Henry (further referred to as mH) and an active circuit Ca creates a negative inductance −Lca of, for example, −15 mH, the resulting inductance Lr is 30 mH. Thus when an active circuit representing a negative inductance is arranged in parallel with the filter inductance Lo, the overall inductance is increased and thus the LCI current is reduced in a frequency range of interest. In the remainder of this document, Negative Impedance Converters NIC are used as active circuits for generating the negative inductance −Lca. Applying other active circuits representing a negative inductance in the disclosed configurations will result in alternative embodiments without departing from the scope of the appended claims.

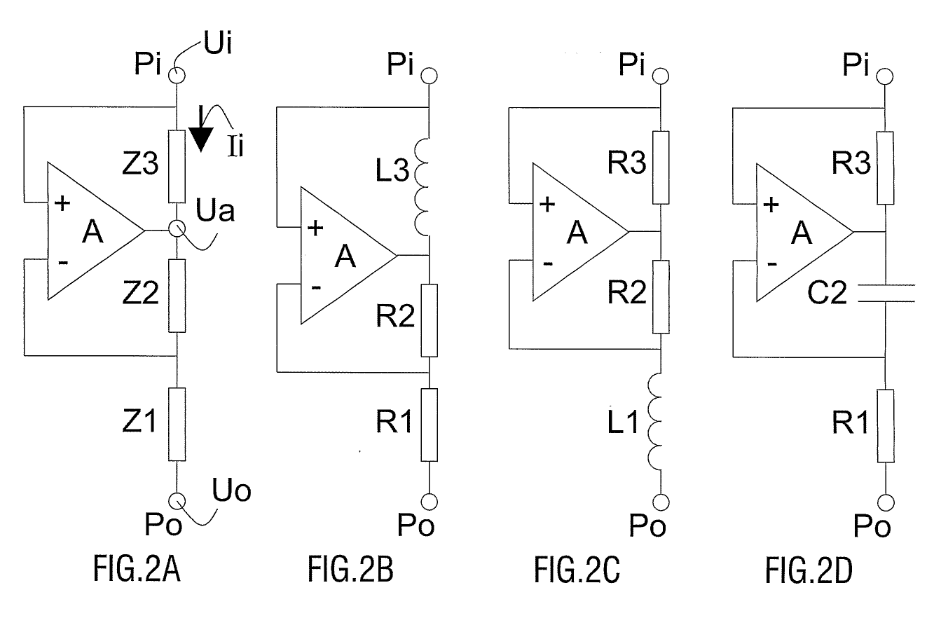

FIG. 2A shows a representation of the Negative Impedance Converter NIC. The Negative Impedance Converter NIC comprises a circuit input terminal Pi and a circuit output terminal Po. This converter further comprises an operational amplifier A and three impedances Z1, Z2, Z3. The first impedance Z1 is connected between the circuit output terminal Po and an inverting input—of the operational amplifier A. The second impedance Z2 is connected between the inverting input—and an output of the operational amplifier A. The third impedance Z3 is connected between the output and a non-inverting input + of the operational amplifier A. Finally, the non-inverting input + is also connected to the circuit input terminal Pi. In literature, the Negative Impedance Converter NIC often only comprises the operational amplifier A together with the first and second impedances Z1, Z2 shown in the arrangement of FIG. 2A. In the case that the first impedance Z1 equals the second impedance Z2, the Negative Impedance Converter NIC represents between the circuit input terminal Pi and the circuit output terminal Po an impedance which is equal to the third impedance Z3 with the sign of the third impedance Z3 inverted. In this document, we consider the third impedance Z3 a part of the Negative Impedance Converter NIC. In FIG. 2A the power supply for the operational amplifier A of the Negative Impedance Converter NIC is not shown. In addition, the operational amplifier A is considered to behave as an ideal operational amplifier, where the inputs −, + represent infinite impedance values and where the amplification factor is sufficiently large to enable the inputs −, + of the operational amplifier to reach an identical potential level. To explain the behavior of the Negative Impedance Converter as shown in FIG. 2A, an input voltage Ui is assumed at the circuit input terminal Pi and an output voltage Uo is assumed at the circuit output terminal Po. The operational amplifier A generates an output voltage Ua at the output of the operational amplifier A, which is equal to:

$$Ua = ( 1 + \frac{Z 2}{Z 1} ) \cdot Ui - \frac{Z 2}{Z 1} \cdot Uo .$$

From this equation, a current Ii running through the third impedance Z3 can be derived:

$$Ii = \frac{Ui - Ua}{Z 3} = \frac{- \frac{Z 2}{Z 1} \cdot ( Ui - Uo )}{Z 3} = \frac{Ui - Uo}{( - \frac{Z 1 \cdot Z 3}{Z 2} )}$$

A resulting replacement impedance Zr of the arrangement shown in FIG. 2A is:

$$Zr = - \frac{Z 1 Z 3}{Z 2} .$$

By implementing different combinations of inductive elements, resistive elements and capacitive elements for the three impedances Z1, Z2, Z3, specific impedance characteristics can be achieved

FIGS. 2B, 2C and 2D show configurations of a Negative Impedance Converter, which represent a negative inductance. The three impedances Z1, Z2, Z3 are substituted by elements to obtain an electronic behavior of the Negative Impedance Converter NIC to represent a negative inductance −Lca. In FIG. 2B the three impedances Z1, Z2, Z3 are the following elements: the first impedance Z1 is a resistive element R1, the second impedance Z2 is a resistive element R2 and the third impedance Z3 is an inductive element L3. A resulting replacement impedance Zrb of the arrangement shown in FIG. 2B is:

$$Zrb = - \frac{R 1 jω L 3}{R 2} = - j ω \frac{R 1 L 3}{R 2} , \\ thus$$

$$Lca = \frac{R 1 L 3}{R 2}$$

In FIG. 2C the three impedances Z1, Z2, Z3 are the following elements: the first impedance Z1 is an inductive element L1, the second impedance Z2 is a resistive element R2 and the third impedance Z3 is a resistive element R3. A resulting replacement impedance Zrc of the arrangement shown in FIG. 2C is:

$$Zrc = - \frac{j ω L 1 R 3}{R 2} = - j ω \frac{L 1 R 3}{R 2} , \\ thus$$

$$Lca = \frac{L 1 R 3}{R 2}$$

In FIG. 2D the three impedances Z1, Z2, Z3 are the following elements: the first impedance Z1 is a resistive element R1, the second impedance Z2 is a capacitive element C2 and the third impedance Z3 is a resistive element R3. A resulting replacement impedance Zrd of the arrangement shown in FIG. 2D is:

$$Zrd = - \frac{R 1 R 3}{1 / ( j ω C 2 )} = - j ω R 1 R 3 C 2 , \\ thus$$

$$Lca = R 1 \cdot R 3 \cdot C 2$$

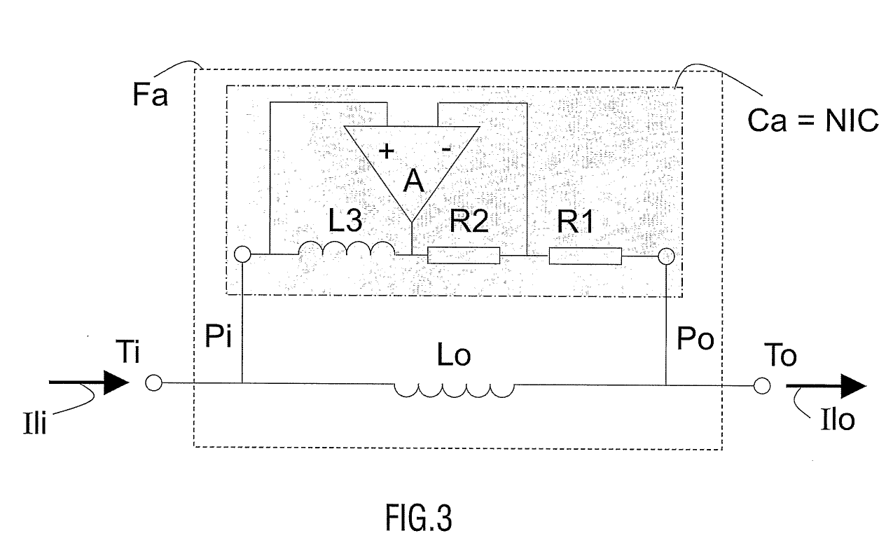

FIG. 3 shows an embodiment of the active EMI filter circuit Fa in accordance with the invention, in which a Negative Impedance Converter NIC is applied. The configuration of the Negative Impedance Converter NIC is identical to the one shown in FIG. 2B. Also in FIG. 3 the power supply for the operational amplifier A is not shown. In addition, again the operational amplifier A is considered to behave as an ideal operational amplifier. The circuit input terminal Pi of the Negative Impedance Converter NIC is connected to the filter input terminal Ti and the circuit output terminal Po is connected to the filter output terminal To, thus the Negative Impedance Converter NIC is arranged in parallel with the filter inductance Lo. Exchanging the shown representation of the Negative Impedance Converter NIC with a different arrangement representing a negative inductance, for example, an arrangement shown in FIG. 2C or 2D, results in an alternative embodiment without departing from the scope of the appended claims. To achieve a higher resulting inductance value Lr compared to the filter inductance Lo, the absolute value Lca of the negative inductance, represented by the Negative Impedance Converter NIC, should be larger than the inductance value of the filter inductance Lo (as has been discussed before). Thus:

|−Lca|>Lo

Because the total impedance value of the closed loop determines the level of the LCI current which flows through the loop, increasing the filter inductance Lo to a resulting inductance Lr by implementing the Negative Impedance Converter NIC in parallel with the filter inductance Lo, reduces the LCI current through the network in a frequency range of interest.

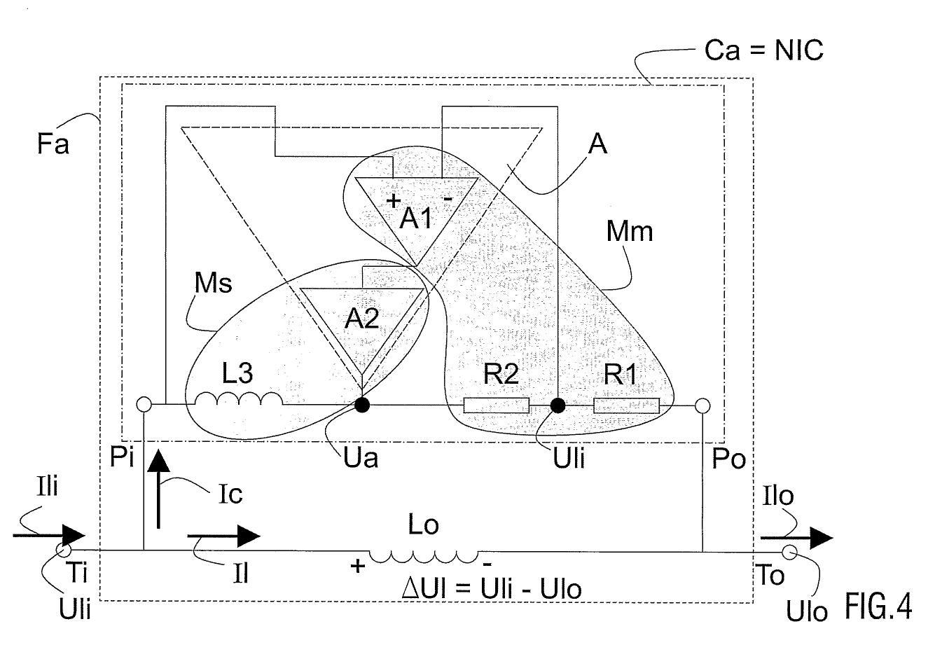

FIG. 4 shows a Negative Impedance Converter NIC which comprises the sensing circuit Mm and suppressing circuit Ms. In this figure, the configuration of the Negative Impedance Converter NIC is identical to the configuration shown in FIG. 3. For ease of explanation the behavior of the shown circuit, the operational amplifier A is split into a differential input stage A1 and an amplifier output stage A2. The sensing circuit Mm comprises the differential input stage A1 of the operational amplifier A together with the resistive elements R1 and R2. The suppressing circuit Ms comprises the amplifier output stage A2 of the operational amplifier A, together with the inductive element L3. An LCI voltage difference ΔUl (ΔUl=Uli−Ulo) is assumed to be present across the filter input terminal Ti and the filter output terminal To. This LCI voltage difference ΔUl causes an LCI inductor current Il to run through the filter inductance Lo. Without the Negative Impedance Converter in parallel with the filter inductance Lo, the LCI current enters via the filter input terminal Ti (indicated with an LCI input current Ili) and leaves via the filter output terminal To (indicated with an LCI output current Ilo. A supply current (not shown) flowing from a supply voltage (not shown) to the load (not shown) also runs through the filter inductance Lo. The supply current has a relatively low frequency with respect to the LCI current. Applying the Negative Impedance Converter in parallel with the filter inductance causes the sensing circuit Mm of the active circuit Ca to sense the LCI voltage difference ΔUl by using the differential input stage A1 of the operational amplifier A in combination with resistive elements R1 and R2. This results in an output voltage Ua of the operational amplifier A of:

$$Ua = U 1 i + ( \frac{R 2}{R 1} ) \cdot Δ U 1$$

The amplifier output stage A2 together with the inductive element L3 responds to the generated output voltage Ua by generating a suppression current Ic, being:

$$Ic = \frac{U 1 i - Ua}{j ω L 3} = - \frac{R 2}{R 1} \frac{1}{j ω L 3} Δ U 1$$

The negative sign indicates that the generated suppression current Ic runs from the circuit input terminal Pi to the filter input terminal Ti (opposite to what is indicated in FIG. 4). The LCI input current Ili is thus reduced by the suppression current Ic.

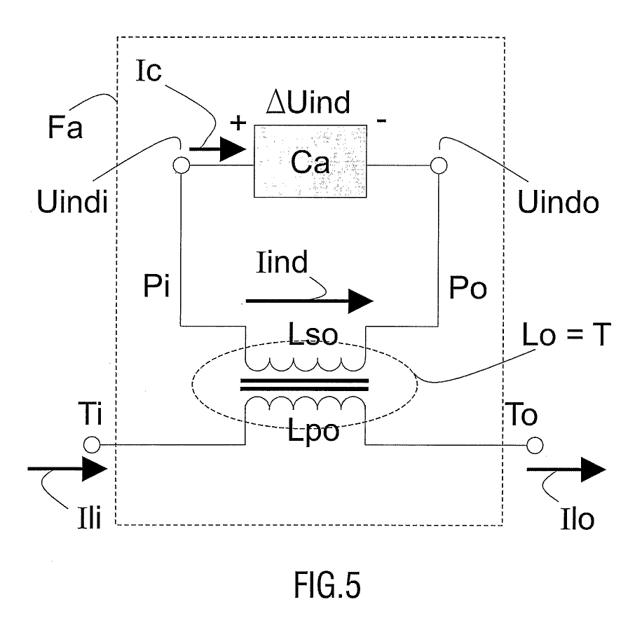

FIG. 5 shows an active EMI filter circuit Fa in accordance with the invention wherein the filter inductance Lo is a transformer T. The primary inductance Lpo of the transformer T is arranged between the filter input terminal Ti and the filter output terminal To. The secondary inductance Lso of the transformer T is arranged in parallel with the active circuit Ca. The secondary inductance Lso is magnetically coupled to the primary inductance Lpo through a magnetization M of the transformer T. Again the LCI voltage difference ΔUl (ΔUl=Uli−Ulo), is assumed to be present across the filter input terminal Ti and the filter output terminal To. Because the secondary inductance Lso is magnetically coupled to the primary inductance Lpo a voltage difference ΔUind (ΔUind=Uindi−Uindo) between the circuit input terminal Pi and the circuit output terminal Po of the active circuit Ca is induced. The induced voltage difference ΔUind is sensed by the sensing circuit Mm of the active circuit Ca and the suppressing circuit Ms suppresses the induced LCI current Iind. The suppression of the induced LCI current Iind in the secondary inductance Lso will, due to the magnetic coupling between the primary inductance Lpo and the secondary inductance Lso, also reduce the LCI current Ili running through the primary inductance Lpo. Using a transformer T as the filter inductance Lo of the active EMI filter circuit Fa offers additional design flexibility. In addition, the transformer T will enable a galvanic separation of the active circuit Ca from the remainder of the network.

FIG. 6 shows an active EMI filter circuit Fa in accordance with the invention, arranged as a mains filter. In this configuration the active EMI filter circuit Fa is arranged in a loop between a load L and a mains M, which is represented by its internal impedance Zm. The mains M is connected between the filter output terminal To of the active EMI filter circuit Fa and a reference potential, which usually is ground. The load L is represented by an impedance Z1 in series with a noise source Vn and is connected between the filter input terminal Ti and through a parasitic impedance Zn to the same reference potential. The supply voltage supplied by the mains M is indicated by Vsup. The load L, in many applications, comprises a power converter which converts the mains voltage into a power converter voltage required by a circuit connected to the power converter. The active EMI filter circuit Fa, connected between the filter input terminal Ti and the filter output terminal To, comprises the filter inductance Lo in parallel with the active circuit Ca. The supply current Isup constitutes a low frequency signal which has a large amplitude and which is hardly influenced by the filter inductance Lo. An LCI current Ili which is assumed to result from the noise source Vn constitutes a high frequency signal which has a small amplitude. The level of the LCI current Ili is dependent on the total impedance of the network shown and largely dependent on the filter inductance Lo. Applying the active circuit Ca in parallel with the filter inductance Lo increases the resulting inductance (as shown before) and reduces the level of the LCI current Ili in a frequency range of interest. This configuration shows that it is relatively simple to implement the active EMI filter circuit Fa, which is a one-port electronic component, into a network. Noise signals Vn will be filtered by the active EMI filter circuit Fa before they leak into the mains M. The filter characteristics of the active EMI filter circuit Fa depend on the selected filter inductance Lo and the characteristics of the active circuit Ca in parallel with the filter inductance Lo.

FIG. 7 shows an active Common Mode EMI filter circuit Fcm in accordance with the invention. A Common Mode filter Fcm comprises two magnetically coupled inductances Lcm1, Lcm2. The first inductance Lcm1 is arranged between a mains output Tmo and a load input Tli. The second inductance Lcm2 is arranged between a load output Tlo and a mains input Tmi. The first inductance Lcm1 and second inductance Lcm2 constitute a common mode transformer Tcm which reduces a high frequency Common Mode LCI signal and hardly influences a low frequency supply signal between the mains M and the load L. The mains M is arranged between the mains input Tmi and the mains output Tmo. The mains M is further connected to a reference potential, which usually is ground. The load L is arranged between the load input Tli and the load output Tlo and is connected through a parasitic inductance Zn and a noise source Vn to the same reference potential. In a Common Mode configuration a first capacitance C1 is arranged between the load input Tli and the load output Tlo and a second capacitance C2 is arranged between the mains output Tmo and the mains input Tmi. For high frequency signals (like an LCI signal) the first capacitance C1 and second capacitance C2 can be considered to short-circuit both the load input Tli with the load output Tlo and the mains output Tmo with the mains input Tmi. Thus the LCI signal will flow as a common mode signal through the common mode transformer Tcm.

The active Common Mode EMI filter circuit Fcm as shown in FIG. 7 comprises an active EMI filter circuit Fa in accordance with the invention, where the first inductance Lcm1 constitutes the filter inductance Lo. The efficiency of the active Common Mode EMI filter circuit Fcm to suppress the Common Mode LCI signal strongly depends on the filter characteristics of the active EMI filter circuit Fa. These filter characteristics depend on the characteristics of the active circuit Ca in combination with the filter inductance Lo. An alternative embodiment of an active Common Mode EMI filter circuit Fcm comprises the active EMI filter circuit Fa where the second inductance Lcm2 constitutes the filter inductance Lo.

FIG. 8 shows an electronic apparatus Sy comprising a Power Converter PC which comprises the active EMI filter circuit Fa in accordance with the invention. The mains M is represented by a mains impedance Zm and supplies a supply current Isup to the electronic apparatus Sy. The electronic apparatus Sy comprises the Power Converter PC, a Drive circuit Dr and a Display Di. The mains M is arranged between ground and the electronic apparatus Sy. The Power Converter PC is arranged between the mains M and the Drive circuit Dr to supply a power converter current Ipc to the Drive circuit Dr. The Drive circuit Dr supplies a drive voltage Vdr to the Display Di. The Display Di has a parasitic capacitance Cp towards ground. The LCI signal which in this embodiment is, for example, the parasitic current Ip through the parasitic capacitance Cp, flows back via the ground terminal of the mains M. The level of the parasitic current Ip depends on the total impedance between the two ground terminals. Increasing this impedance, for example, by adding the active EMI filter circuit Fa to the Power Converter PC suppresses the parasitic current Ip. Electronic apparatuses Sy are, for example, a television or computer monitor which comprises a Power Converter PC, a Drive circuit Dr and a Display circuit Di; or, for example, a DVD-player which comprises a Power Converter PC, a signal converting circuit and a drive circuit; or, for example, a refrigerator which comprises a Power Converter PC, a control circuit and a motor-drive circuit.

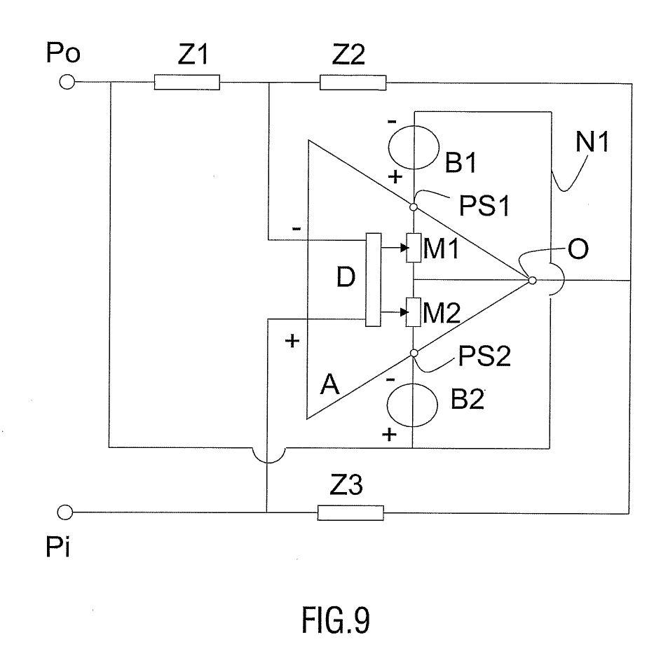

FIG. 9 shows a representation of the Negative Impedance Converter NIC together with a possible power supply network for the operational amplifier A. The Negative Impedance Converter NIC comprises a circuit input terminal Pi and a circuit output terminal Po. This converter further comprises an operational amplifier A and three impedances Z1, Z2, Z3. The first impedance Z1 is connected between the circuit output terminal Po and an inverting input—of the operational amplifier A. The second impedance Z2 is connected between the inverting input—and an output of the operational amplifier A. The third impedance Z3 is connected between the output and a non-inverting input + of the operational amplifier A. Finally, the non-inverting input + is also connected to the circuit input terminal Pi.

The operational amplifier A comprises an output stage M1, M2 and a driver D. The output stage M1, M2 comprises a series arrangement of two controllable impedances. The controllable impedance M1 has a control input to receive a control signal from the driver D and a main current path arranged between the output O of the operational amplifier A and the power supply input PS1. The controllable output stage M2 has a control input to receive a control signal from the driver D and a main current path arranged between the output O of the operational amplifier A and the power supply input PS2. The driver has inputs connected to the inverting—and non-inverting inputs + of the operational amplifier A. A power supply B1 is connected between the power supply input PS1 and a node N1 to supply a positive supply voltage to the power supply input PS1. A power supply B2 is connected between the power supply input PS2 and the node N1 to supply a negative power supply voltage to the power supply input PS2. The node Ni is connected to the circuit output terminal Po. The power supplies B1 and B2 may be batteries. The driver D controls the impedance of the two controllable impedances such that the voltage difference between the inverting input—and the non-inverting input + of the operational amplifier A becomes zero. The controllable impedances M1 and M2 may be MOSFETs. The control input now is the gate, and the main current path is formed by the drain-source path of the MOSFET.

It has to be noted that the power supplies B1 and B2 do not require any connection to outside the Negative Impedance Converter NIC through which current flows into or out of the NIC. What really counts is that the node N1 is not connected to the circuit input terminal Pi of the Negative Impedance Converter NIC. Consequently, the Negative Impedance Converter NIC is a pure one port. Even if the power supplies B1 and B2 are generated by floating windings on a transformer outside the Negative Impedance Converter NIC, still, netto, no current flows into or out of the Negative Impedance Converter via these windings.

Although, until now, the active circuit Ca is connected with the circuit input terminal Pi to the filter input terminal Ti and with the circuit output terminal Po to the filter output terminal To it is also possible to connect the circuit input terminal Pi to the filter output terminal To and the circuit output terminal Po to the filter input terminal Ti.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

1. An active Electromagnetic Interference filter circuit (Fa) for suppressing a Line Conducted Interference signal and comprising
a filter input terminal (Ti) and a filter output terminal (To),
a filter inductance (Lo) being arranged between the filter input terminal (Ti) and the filter output terminal (To) for carrying a supply current between a supply voltage (Vsup) and a load (L), and
an active circuit (Ca) arranged in parallel with the filter inductance (Lo) through a circuit input terminal (Pi) and a circuit output terminal (Po) of the active circuit (Ca), the active circuit (Ca) further comprising:
(i) sensing means (Mm) for sensing the Line Conducted Interference signal between the circuit input terminal (Pi) and the circuit output terminal (Po) to obtain a sense signal, and
(ii) suppressing means (Ms) for supplying, in response to the sense signal, a counteracting voltage between the circuit input terminal (Pi) and the circuit output terminal (Po) or to supply a counteracting current (Ic) from the circuit input terminal (Pi) to the circuit output terminal (Po) for counteracting the Line Conducted Interference signal.

2. An active Electromagnetic Interference filter circuit (Fa) as claimed in claim 1, wherein the sensing means (Mm) comprises a voltage sensing circuit for obtaining the sense signal being a sensed voltage and wherein the suppressing means (Ms) comprises a current source being controlled by the sensed voltage to supply the counteracting current (Ic).

3. An active Electromagnetic Interference filter circuit (Fa) as claimed in claim 1, wherein the filter inductance (Lo) has a positive inductance value and the active circuit (Ca) comprises a negative inductance generating means for providing a negative inductance value (−Lca).

4. An active Electromagnetic Interference filter circuit (Fa) as claimed in claim 3, wherein the negative inductance generating means comprises a Negative Impedance Converter (NIC).

5. An active Electromagnetic Interference filter circuit (Fa) as claimed in claim 4, wherein the Negative Impedance Converter (NIC) comprises:
an operational amplifier (A),
a first impedance (Z1, R1, L1) arranged between an inverting input of the operational amplifier (A) and the circuit output terminal (Po),
a second impedance (Z2, R2, C2) arranged between the inverting input of the operational amplifier (A) and an output of the operational amplifier (A) and
a third impedance (Z3, R3, L3) arranged between the output of the operational amplifier (A) and a non-inverting input of the operational amplifier (A), the non-inverting input of the operational amplifier (A) being further coupled to the circuit input terminal (Pi).

6. An active Electromagnetic Interference filter circuit (Fa) as claimed in claim 5, wherein the first impedance (Z1, R1, L1), the second impedance (Z2, R2, C2) and the third impedance (Z3, R3, L3) being selected to represent (i) a resistive element (R1), a resistive element (R2) and an inductive element (L3), respectively, or (ii) an inductive element (L1), a resistive element (R2) and a resistive element (R3), respectively, or (iii) a resistive element (R1), a capacitive element (C2) and a resistive element (R3), respectively.

7. An active Electromagnetic Interference filter circuit (Fa) as claimed in claim 1, wherein the filter inductance (Lo) of the active Electromagnetic Interference filter circuit (Fa) comprises a transformer (T) having a primary inductance (Lpo) being arranged between the filter input terminal (Ti) and the filter output terminal (To), and a secondary inductance (Lso) being magnetically coupled to the primary inductance (Lpo) and being arranged in parallel with the active circuit (Ca) through the circuit input terminal (Pi) and the circuit output terminal (Po).

8. A Common Mode suppression filter (Fcm) having a first inductance (Lcm1) for carrying a supply current (Isup) from a supply voltage (Vsup) to a load (L) and a second inductance (Lcm2), for carrying a return current from the load (L) to the supply voltage (Vsup), the first inductance (Lcm1) and the second inductance (Lcm2) being magnetically coupled for suppressing a Common Mode Line Conducted interference signal, the Common Mode suppression filter comprising the active Electromagnetic Interference filter circuit (Fa) as claimed in claim 1, wherein the filter inductance (Lo) constitutes the first inductance (Lcm1) or wherein the filter inductance (Lo) constitutes the second inductance (Lcm2).

9. A power converter (PC) for receiving a supply current Isup from the mains and to supply a power converter current Ipc to the load, the power converter (PC) comprises the active EMI filter circuit (Fa) as claimed in claim 1, wherein the filter inductance Lo is arranged for carrying either the supply current Isup or the power converter current Ipc.

10. An electronic apparatus (Sy) comprising a power converter as claimed in claim 10, wherein the load (L) comprises a circuit of the electronic apparatus (Sy).
